(19) United States
(12) Patent Application Publication
(10) Pub. No.: US 2019/0353823 A1
(43) Pub. Date: Nov. 21, 2019

(54) Systems and Methods for Predicting or Identifying Underlying Features of Multidimensional Well-Logging Measurements

(71) Applicant: Schlumberger Technology Corporation

(72) Inventor: Vivek Anand, Sugar Land, TX (US)

(21) Appl. No.: 15/771,412

(22) PCT Filed: Oct. 14, 2016
(86) PCT No.: PCT/US2016/056937

§ 371 Date: Apr. 27, 2018

Related U.S. Application Data
(60) Provisional application No. 62/249,257, filed on Oct. 31, 2015.

(51) Int. Cl. G01V 5/04; E21B 47/12; G01R 33/46

(52) U.S. Cl. CPC G01V 5/04; G01R 33/4633; E21B 47/123

(57) ABSTRACT

Systems and methods are provided for predicting or identifying underlying features in multidimensional logging measurements. Such a system may include a downhole tool and a data processing system. The downhole tool may obtain multidimensional well-logging measurements in a wellbore. The data processing system may predict or identify underlying features in the multidimensional well-logging measurements—which would be otherwise indiscernible to a human—by decomposing a matrix based on the multidimensional well-logging measurements into a first component matrix and a second component matrix. The first component matrix describes the underlying features and the second component matrix describes proportions of the underlying features. The underlying features of the multidimensional well-logging measurements correspond to properties in the wellbore that can be identified and presented visually to enable well management based on the properties in the wellbore.

### CROSS-REFERENCE TO RELATED APPLICATIONS

The present application claims priority to U.S. Provisional Application 62/249,257 filed Oct. 31, 2015, the entirety of which is incorporated by reference.

### BACKGROUND

This disclosure relates to predicting or identifying features of well-logging measurements and, more particularly, to predicting or identifying underlying features of multidimensional well-logging measurements.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Numerous well-logging tools may be used to identify characteristics of a well drilled into a geological formation. These may include electrical, mechanical, electromagnetic, and/or magnetic measurements. The measurements may be transformed to identify petrophysical properties such porosity, permeability, relative proportions of water and hydrocarbons, and so forth, which may provide highly valuable information to human operators to manage the well.

Some well-logging tools obtain measurements of one dimension that can be represented in a straightforward way in a well log. A well log is a form of visualization of well-logging measurements over depths of the well to enable a human operator to better understand the characteristics of the well at particular depths. Well-logging measurements of a single dimension may lend themselves well to such straightforward forms of visualization.

Many downhole tools, however, may produce multidimensional logging measurements. For example, a nuclear magnetic resonance (NMR) downhole tool may obtain multidimensional logging measurements that include hundreds of data points at each depth. Indeed, NMR tools can measure distributions of a first relaxation time T1, a second relaxation time T2, or diffusion, or a combination of these. For example, an NMR tool may measure just T2 distribution, which can have several amplitudes (e.g. 30). Or the tool may measure a joint T1-T2 distribution or T1-T2-D distribution, in which case the dimensionality is even higher (30×30×30). Each data point may include an amplitude of relaxation time or diffusion distribution or combination thereof. Certain patterns among the data points may arise due to particular petrophysical or fluid characteristics of the well. Owing to the relatively high dimensionality of these measurements, however, it may be difficult or impossible for a human to discern the particular properties based on these measurements. Instead, multidimensional logging measurements, such as those from NMR tools, may be transformed into water and hydrocarbon volumes using relatively simple and empirical models. In situations where the multidimensional logging measurements are highly mixed or include novel patterns not explained by the relatively simple empirical models, however, the underlying features of the multidimensional well-logging measurements may remain hidden or misunderstood.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

This disclosure relates to systems and methods for predicting or identifying underlying features in multidimensional logging measurements. In one example, a system may include a downhole tool and a data processing system. The downhole tool may obtain multidimensional well-logging measurements in a wellbore. The data processing system may predict or identify underlying features in the multidimensional well-logging measurements—which would be otherwise indiscernible to a human—by decomposing a matrix based on the multidimensional well-logging measurements into a first component matrix and a second component matrix. The first component matrix describes the underlying features and the second component matrix describes proportions of the underlying features. The underlying features of the multidimensional well-logging measurements correspond to properties in the wellbore that can be identified and presented visually to enable well management based on the properties in the wellbore.

In another example, a method includes placing a downhole tool in a wellbore, obtaining multidimensional well-logging measurements in the wellbore. The multidimensional well-logging measurements include underlying features in varying proportions at different depths of the wellbore, and the underlying features or the varying proportions of the underlying features, or both, may not be fully discernible to a human in the form of the multidimensional well-logging measurements as obtained by the downhole tool. As such, one or more processors may be used to predict or identify the underlying features or the varying proportions of the underlying features, or both, from the multidimensional well-logging measurements by decomposing a matrix based on the multidimensional well-logging measurements into a first component matrix and a second component matrix. The first component matrix may include basis vectors that describe the underlying features and the second component matrix may include the varying proportions of the underlying features. The one or more processors may generate a visualization based on the underlying features or the varying proportions of the underlying features, or both, to enable well management based on the underlying features or the varying proportions of the underlying features, or both.

In another example, one or more tangible, non-transitory, machine-readable media may include instructions to receive multidimensional well-logging measurements obtained by a downhole tool at different depths of a wellbore and process the multidimensional well-logging measurements to identify underlying features not otherwise readily discernible to a human. Indeed, the multidimensional well-logging measurements may include underlying features in varying proportions at different depths of the wellbore, and the underlying features or the varying proportions of the underlying features, or both, may not be fully discernible to a human in the form of the multidimensional well-logging measurements as obtained by the downhole tool. The instructions may include normalizing the multidimensional well-logging measurements and arranging the normalized multidimensional well-logging measurements into a column data matrix that can be represented as a product of a first component matrix and a second component matrix, in which the first component matrix includes basis vectors that describe the underlying features and the second component matrix includes the varying proportions of the underlying features. The instructions may include solving a first optimization problem to obtain basis vectors of the first component matrix that represent the underlying features of the multidimensional well-logging measurements, normalizing the basis vectors of the first component matrix, and solving a second optimization problem to obtain values of the second component matrix that represent the proportions of the underlying features of the multidimensional well-logging measurements. The basis vectors of the first component matrix or the values of the second component matrix, or both, may be used to generate a visualization of properties in the wellbore to enable well management based at least in part on the visualization.

Various refinements of the features noted above may be undertaken in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a schematic diagram of a well-logging system that may obtain multidimensional logging measurements and predict or identify underlying features using the multidimensional logging measurements, in accordance with an embodiment;

FIG. 2 is a flowchart of a method for using the system of FIG. 1, in accordance with an embodiment;

FIG. 3 is an example of simulated underlying features relating to petrophysical characteristics that may appear in multidimensional nuclear magnetic resonance (NMR) well-logging measurements, in accordance with an embodiment;

FIG. 4 illustrates admixtures of the underlying features shown in FIG. 3 in various proportions to represent simulated examples of multidimensional NMR well-logging measurements, in accordance with an embodiment;

FIG. 5 is a flowchart of a method for predicting or identifying underlying features of multidimensional well-logging measurements such as the simulated examples of the multidimensional well-logging measurements of FIG. 4, in accordance with an embodiment;

FIG. 6 illustrates underlying features of the multidimensional well-logging measurements identified according to the method of FIG. 5;

FIG. 7 plots the true value of the proportion of the underlying features of the multidimensional well-logging measurements in comparison to the predicted value of the underlying feature as determined according to the method of FIG. 5; and

FIG. 8 is a well log representing a visualization of the underlying features determined according to this disclosure to enable well management, in accordance with an embodiment.

### DETAILED DESCRIPTION

One or more specific embodiments of the present disclosure will be described below.

These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Many downhole tools used for logging a well obtain multidimensional logging measurements. These multidimensional logging measurements may be so complex that it may be difficult or impossible for a human operator, or even relatively simple models, to identify underlying features amid the multidimensional logging measurements, since the underlying features may not be separated and may overlay. Accordingly, this disclosure describes systems and methods that may be used to predict or identify underlying features in multidimensional logging measurements.

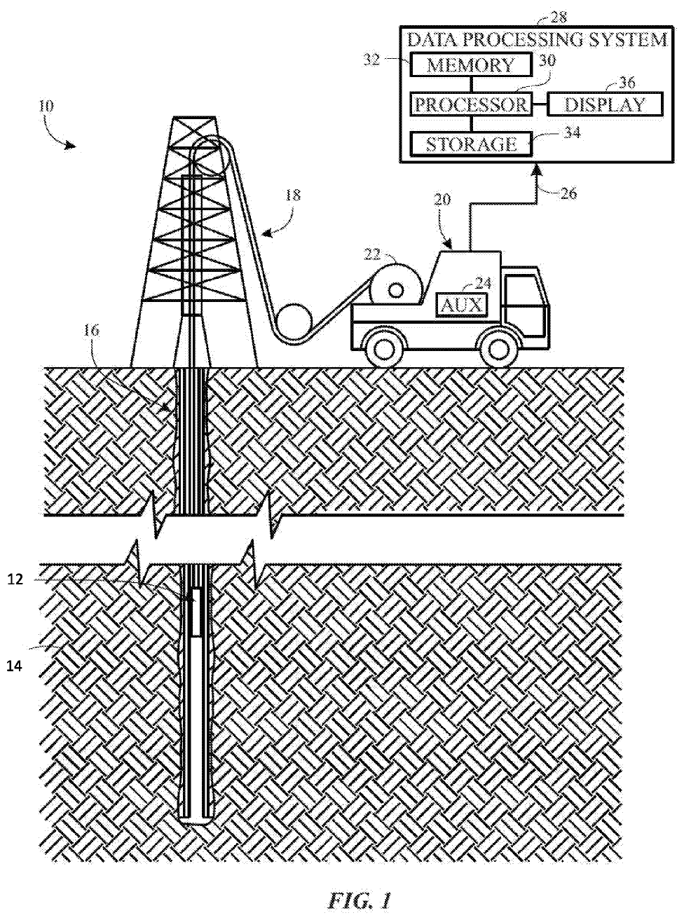

With this in mind, FIG. 1 illustrates a well-logging system 10 that may employ the multidimensional measurement identification and/or visualization systems and methods of this disclosure. The well-logging system 10 may be used to convey a downhole tool 12 through a geological formation 14 via a wellbore 16. The downhole tool 12 may be conveyed on a cable 18 via a logging winch system 20. Although the logging winch system 20 is schematically shown in FIG. 1 as a mobile logging winch system carried by a truck, the logging winch system 20 may be substantially fixed (e.g., a long-term installation that is substantially permanent or modular). Any suitable cable 18 for well logging may be used. The cable 18 may be spooled and unspooled on a drum 22 and an auxiliary power source 24 may provide energy to the logging winch system 20 and/or the downhole tool 12.

Although the downhole tool 12 is described as a wireline downhole tool, it should be appreciated that any suitable conveyance may be used. For example, the downhole tool 12 may instead be conveyed as a logging-while-drilling (LWD) tool as part of a bottom hole assembly (BHA) of a drill string, conveyed on a slickline or via coiled tubing, and so forth. For the purposes of this disclosure, the downhole tool 12 may be any suitable measurement tool that obtains multidimensional logging measurements through depths of the wellbore 16.

Many types of downhole tools may obtain multidimensional logging measurements in the wellbore 16. These include, for example, nuclear magnetic resonance (NMR) tools such as the Combinable Magnetic Resonance (CMR) tool, the Magnetic Resonance Scanner (MRX) tool, and the ProVISION tool by Schlumberger Technology Corporation. For each depth of the wellbore 16 that is measured, NMR tools generate multidimensional logging measurements that include a distribution of amplitudes of T2 relaxation time, T1 relaxation time, diffusion, or a combination thereof. Other downhole tools that obtain multidimensional logging measurements may include gamma ray spectroscopy tools e.g. Schlumberger Litho Scanner tool which measures the multi-dimensional capture and inelastic gamma ray spectra. This list is intended to present certain examples and is not intended to be exhaustive. Indeed, any suitable downhole tool 12 that obtains multidimensional logging measurements may benefit from the systems and methods of this disclosure.

The downhole tool 12 may provide such multidimensional logging measurements 26 to a data processing system 28 via any suitable telemetry (e.g., via electrical signals pulsed through the geological formation 14 or via mud pulse telemetry). The data processing system 28 may process the multidimensional logging measurements 26 to identify patterns in the multidimensional logging measurements 26. The patterns in the multidimensional logging measurements 26 may indicate certain properties of the wellbore 16 (e.g., porosity, permeability, relative proportions of water and hydrocarbons, and so forth) that would be otherwise indiscernible by a human operator.

To this end, the data processing system 28 thus may be any electronic data processing system that can be used to carry out the systems and methods of this disclosure. For example, the data processing system 28 may include a processor 30, which may execute instructions stored in memory 32 and/or storage 34. As such, the memory 32 and/or the storage 34 of the data processing system 28 may be any suitable article of manufacture that can store the instructions. The memory 32 and/or the storage 34 may be ROM memory, random-access memory (RAM), flash memory, an optical storage medium, or a hard disk drive, to name a few examples. A display 36, which may be any suitable electronic display, may provide a visualization, a well log, or other indication of properties of the wellbore 16 based on the multidimensional logging measurements 26.

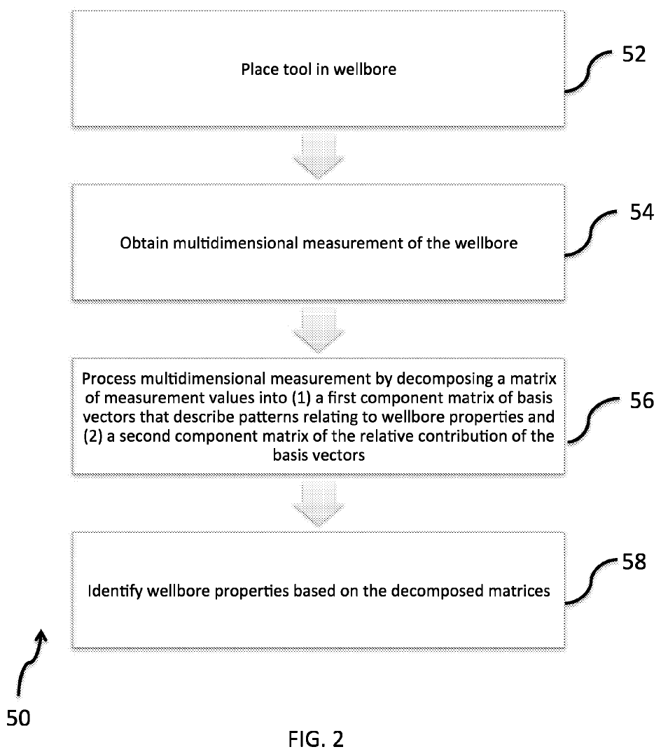

Indeed, as shown by a flowchart 50 of FIG. 2, the downhole tool 12 may be placed in the wellbore 16 (block 52) and a multidimensional measurement of the wellbore 16 may be obtained (block 54). The data processing system 28 may predict or identify underlying features of the multidimensional measurement (block 56). For example, the data processing system 28 may process the multidimensional measurement by decomposing a matrix of measurement values into (1) a first component matrix of bases factors that describe patterns relating to the wellbore properties and (2) a second component matrix of the relative contribution of the bases factors. From these decomposed matrixes, the underlying features may be used to identify or predict properties relating to the wellbore 16, such as fluid, properties, formation properties, and so forth based on the decomposed matrixes (block 58).

Indeed, large quantities of data may be acquired using logging tools that obtain multidimensional logging measurements, such as NMR measurements. In particular, NMR measurements may include hundreds of data points. Each data point may represent an amplitude of T2 relaxation time, T1 relaxation time or diffusion or any combination thereof. Before continuing, it should be appreciated that NMR tools do not directly measure T2, T1 or diffusion distributions. The NMR signals (called echoes) go through an inversion process to produce the multidimensional distributions. The echoes need not be positive either but the multidimensional distributions contain positive amplitudes. As such, NMR measurements may include quantities that are positive and measured as a function of depth through the wellbore 16. Using the systems and methods of this disclosure, underlying features in such high-dimensionality multidimensional logging measurements may be detected. Moreover, the proportions of these underlying features in the multidimensional logging measurements may be identified, as well.

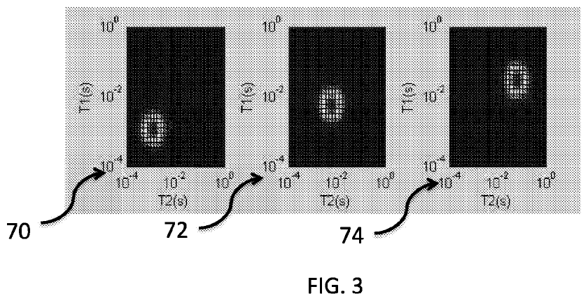

To help illustrate, FIG. 3 represents plots of multidimensional logging measurements, each of which describing one specific underlying feature that represents a particular wellbore 16 property. As shown in FIG. 3, plots 70, 72, and 74 each plot an amplitude of a first relaxation time (T1) against an amplitude of a second relaxation time (T2) in units of seconds, where the amplitude values appear in the plot 70, 72, and 74 as Gaussian peaks (represented in FIG. 3 by pixels of different shades or colors). Moreover, while the features represented in the plots 70, 72, and 74 of FIG. 3 are shown as Gaussian peaks, it should be understood that underlying features of multidimensional logging measurements may take other forms. That is, the Gaussian peaks illustrated in FIG. 3 are represented by way of example and are not intended to be limiting. The particular shape or appearance of a particular underlying feature of multidimensional logging measurements may take other forms. Each underlying feature may be understood to be caused by a particular characteristic of the wellbore 16 environment (e.g., a particular lithology, porosity, permeability, proportion of hydrocarbon to water, presence or absence of gas, and so forth).

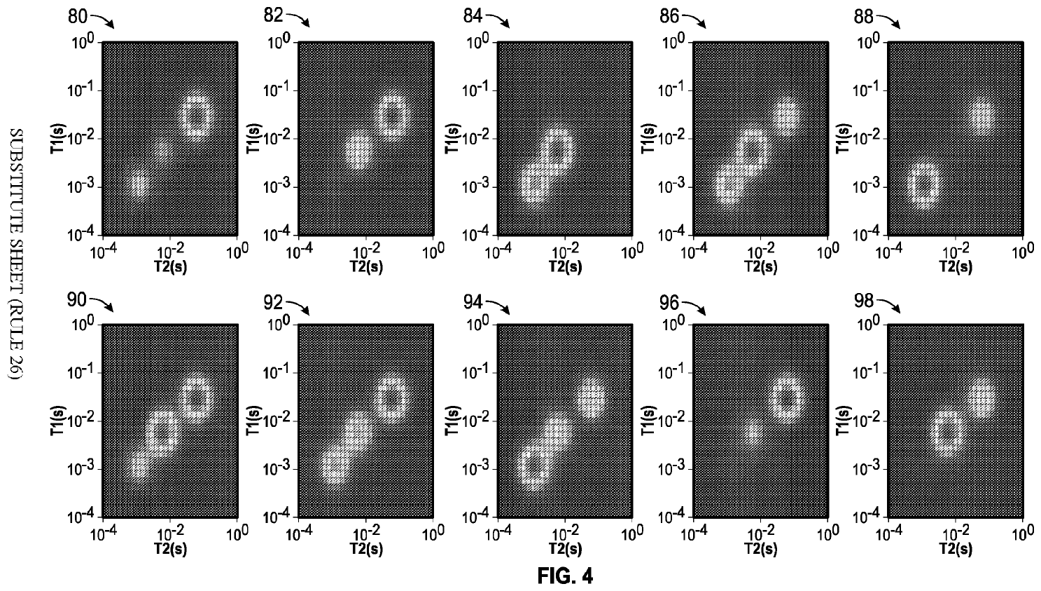

In the plots 70, 72, and 74 of FIG. 3, the underlying features of the multidimensional logging measurements represent a response by the downhole tool 12 to some particular fluid property or some particular lithology found in the wellbore 16 or the formation 12. While each underlying feature of the multidimensional logging measurements is shown separately in the plots 70, 72, and 74, in practice, the underlying features represented in FIG. 3 may not appear in such a pure form. Rather, actual multidimensional well-logging measurements may include admixtures of underlying features at various depths through the wellbore 16. Examples of such admixtures appear in FIG. 4. Specifically, FIG. 4 provides ten variations of admixtures of the discrete underlying features of FIG. 3 in plots 80, 82, 84, 86, 88, 90, 92, 94, 96, and 98 in FIG. 4. Based solely on the visualization of the admixed logging measurements provided by way of example in FIG. 4, it may be difficult or impossible for a human to fully discern which underlying features appear in the wellbore 16 and/or in what proportion.

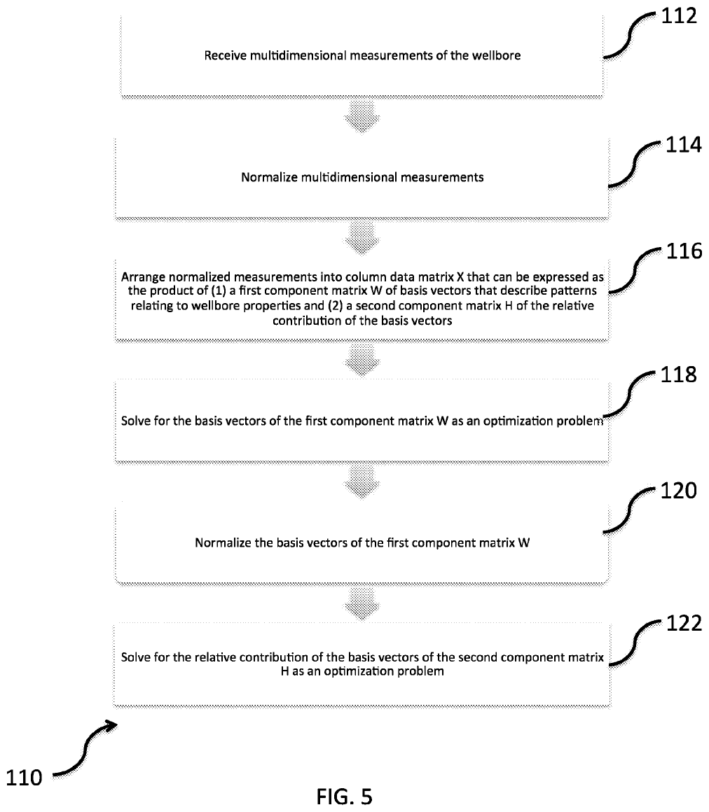

A flowchart 110 of FIG. 5 provides one manner of predicting or identifying the underlying features and/or the proportions of the underlying features from multidimensional logging measurements, such as those represented by way of example in FIG. 4. The flowchart 110 of FIG. 5 may correspond to block 56 of FIG. 2. Multidimensional logging measurements obtained by the downhole tool 12 may be received into the data processing system 28 (block 112). The multidimensional logging measurements may be normalized (block 114). Any suitable normalization factor may be used. In one example, the multidimensional logging measurements may be normalized by the sum of all of the components of a data vector that represents the multidimensional logging measurements. Additionally or alternatively, other statistical measures, such as a mean or maximum of the data vector, may be used to normalize the data.

The normalized logging measurements may be arranged into a column data matrix X (block 116). The dimensions of the column data matrix X are N×M, where N represents the dimension of the measurement, and M represents the number of realizations to be processed. Here, it should also be appreciated that all of the entries of the column data matrix X are non-negative (i.e., X≥0). The column data matrix X may be expressed approximately as the product of two non-negative matrixes as shown below:

X≈WH

W≥0

H≥0 (1).

In other words, the column data matrix X may be expressed approximately as a linear (additive) combination of basis factors contained in first component matrix W in proportions contained in second component matrix H. Therefore, the column data matrix X may be decomposed into constituent parts to identify the underlying features as basis vectors in first component matrix matrix W and the proportions of the underlying features in second component matrix H.

The basis vectors of the first component matrix W may be solved as an optimization problem (block 118). For example, a solution to Equation 1 may be obtained by solving the following optimization problem:

$${min}_{W , H} f ( W , H ) = \frac{1}{2} {‖ X - WH ‖}_{F}^{2} s . t . W , H \geq 0 \qquad ( 2 )$$

∥ ∥_{F} refers to the Frobenius norm of a matrix and min refers to the minima of a function f. The Frobenius norm of an m×n matrix A is defined as

$${‖ A ‖}_{F} = \sqrt{{\sum }_{i = 1}^{m} {\sum }_{j = 1}^{n} {\vert {a}_{ij} \vert}^{2}}$$

Further, additional constraints on the sparsity and smoothness on matrices W and H can be added as shown below:

$${min}_{W , H} f ( W , H ) = \frac{1}{2} {‖ X - WH ‖}_{F}^{2} + ( {α}_{1} {‖ W ‖}_{2} + {α}_{2} {‖ W ‖}_{1} ) + ( {β}_{1} {‖ H ‖}_{2} + {β}_{2} {‖ H ‖}_{2} ) s . t W , H \geq 0 , \qquad ( 3 )$$

where ∥ ∥₁ and ∥ ∥₂ refer to L1 and L2 norms of the matrices W and H. The parameters α₁ and β₁ determine respectively the degree of regularization and sparsity of matrix W. Similarly α₂ and β₂ determine the degree of regularization and sparsity of matrix H. The L2 norm may be raised to the power of two in some examples. The Lp norm of a matrix may be defined as follows:

$${‖ Y ‖}_{p} = {( {\sum }_{i , j} {\vert {Y}_{ij} \vert}^{p} )}^{1 / p} , \qquad ( 4 )$$

where Yᵢⱼ is the matrix entry in the ith row and jth column of the matrix Y. The L1 or L2 norm may be understood to take the form of Equation 4 above, with 1 or 2 replacing p, respectively.

It should be appreciated that any suitable method may be used to solve the optimization problem. By solving this optimization problem, the basis vectors contained in the matrix W may be identified.

After determining the basis vectors of the first component matrix W, these values may be normalized (block 120). The normalization factor used to normalize the column data matrix X may also be used to normalize the basis vectors of the first component matrix W. For example, both the data vectors contained by the column data matrix X and the basis vectors contained in the first component matrix W may be normalized with a corresponding sum of the components. Additionally or alternatively, the basis vectors of the first component matrix W may be normalized independently of the column data matrix X.

The relative contribution of the basis vectors as described by the second component matrix H may be determined by solving another optimization problem (block 122). For example, this may be performed by solving the following optimization problem:

min∥Xᵢ−Wfᵢ∥ₚ,s.t.fᵢ≥0,i=1,2 . . . M (5),

Where ∥ ∥ₚ refers to the Lp norm of a vector defined in Eq 4 and M refers to number of realizations to be processed.

It should be appreciated that any suitable norm used to solve the optimization problem of Equation 5. In one example, the L2 norm may be solved.

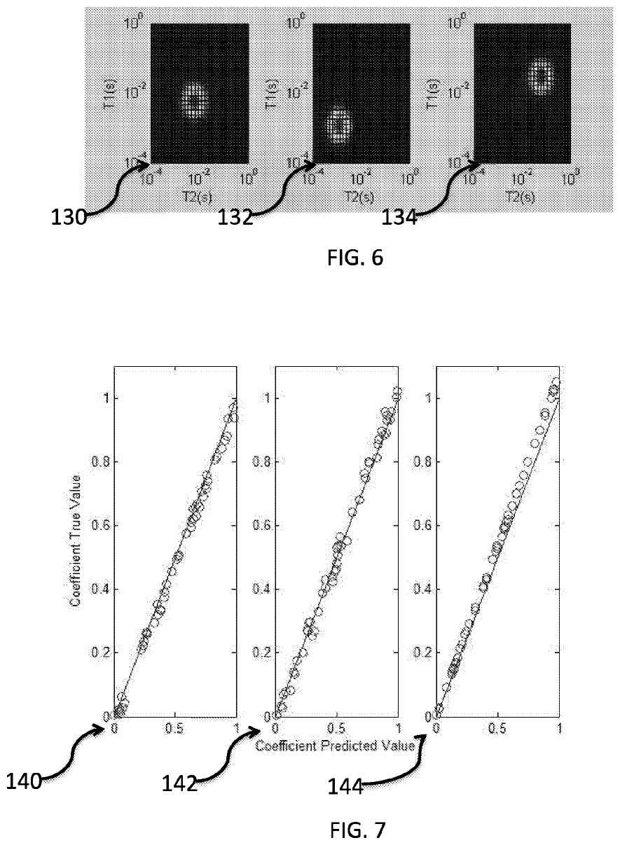

FIGS. 6 and 7 provide an example of the results of using the method of FIG. 5 on 50 simulated multidimensional logging measurements, such as 50 of the various admixed measurements simulated in FIG. 4. In FIG. 6, the underlying features of the multidimensional logging measurements—as represented by the basis vectors of the first component matrix W—are shown to have been accurately predicted or identified from the add mix simulated logging measurements. As seen in FIG. 6, plots 130, 132, and 134 represent T1-T2 maps in a similar manner to the plots of FIG. 3. Indeed, the predicted or identified underlying features shown in the plots 130, 132, and 134 of FIG. 6 correspond respectively to the simulated individual underlying features shown in the plots 72, 70, and 74 of FIG. 3. In other words, even though the simulated multidimensional logging measurements contained multiple admixed underlying features, the systems and methods of this disclosure accurately predicted or identified the individual component underlying features.

Moreover, the systems and methods of this disclosure may also provide an accurate prediction or identification of the relative proportions of the underlying features. FIG. 7 illustrates three plots 140, 142, and 144 that correspond to the predicted or identified proportions of underlying features of the plots 130, 132, and 134 of FIG. 6. The plots 140, 142, and 144 each plot the accuracy of the estimated proportion of the underlying features of the plots 130, 132, and 134 in various admixed simulated multidimensional logging measurements. In particular, the plots 140, 142, and 144 plot a relationship between a coefficient or proportion true value (ordinate) and the coefficient or proportion that was estimated according to the systems and methods of this disclosure (abscissa). Each circle on the plots 140, 142, and 144 represents a data point corresponding to the accuracy of the representation of one of the 50 admixed simulated multidimensional logging measurements. A line of slope 1 represents a perfect relationship—that is, 1:1 relationship—between the coefficient or proportion true value and the coefficient or proportion that was estimated according to the systems and methods of this disclosure. As can be seen in the plots 140, 142, and 144, the predicted or identified coefficient or proportions tend to correspond well to the true coefficient or proportion values.

By identifying the underlying features of multidimensional logging measurements, particular petrophysical or fluid properties that caused the multidimensional logging measurement to contain the underlying features may be identified and used for well management. The underlying features may be identified to be due to fluid or petrophyiscal properties in any suitable way, such as via simulations or empirical studies. Thereafter, the properties may be presented in a form much more easily understood by humans than the form of the multidimensional logging measurement data. For example, the identified properties and/or the proportion of the properties may be presented in a well log to enable a human to make valuable well management decisions, which may not otherwise be possible without the systems and methods of this disclosure.

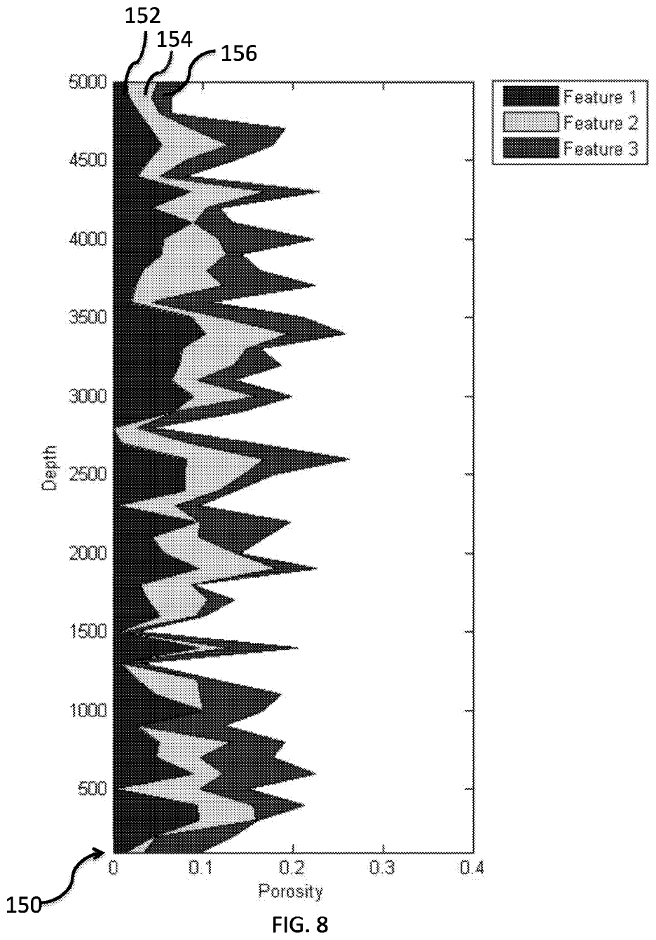

Additionally or alternatively, the underlying features of the multidimensional logging measurements may be presented in a visualization such as a well log 150 shown in FIG. 8. The well log 150 represents the varying amounts of three identified underlying features 152, 154, and 156 over depth (ordinate) that correspond to values of porosity (abscissa) in the wellbore 16. By presenting the identified underlying features in a visualization such as this, a human operator may be able to more effectively make decisions relating to the management and/or operation of the well. Indeed, the visualization product that may be provided may add significant value to any suitable multidimensional well-logging measurements from which a human would be otherwise unable to fully discern the underlying features and/or the contributions of those underlying features.

Moreover, it should be understood that the visualization may also take the form of the underlying features themselves that, having been predicted or identified according to the systems and methods of this disclosure, may be presented in the manner of FIG. 6.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. A system comprising:
a downhole tool configured to obtain multidimensional well-logging measurements in a wellbore; and
a data processing system configured to predict or identify underlying features in the multidimensional well-logging measurements that would be otherwise indiscernible to a human by decomposing a matrix based on the multidimensional well-logging measurements into a first component matrix and a second component matrix, wherein the first component matrix comprises basis vectors that describe the underlying features and the second component matrix comprises proportions of the underlying features, wherein the underlying features of the multidimensional well-logging measurements correspond to properties in the wellbore that can be identified and presented visually to enable well management based on the properties in the wellbore.

2. The system of claim 1, wherein the downhole tool comprises a nuclear magnetic resonance (NMR) tool configured to obtain the multidimensional well-logging measurements in the wellbore.

3. The system of claim 2, wherein the multidimensional well-logging measurements comprise an amplitude of a first relaxation time, or an amplitude of a second relaxation time, or an amplitude of diffusion or a combination thereof.

4. The system of claim 2, wherein the downhole tool is configured to obtain the multidimensional well-logging measurements at a plurality of depths in the wellbore, the multidimensional well-logging measurements obtained at each of the plurality of depths comprising hundreds of data points.

5. The system of claim 1, wherein the properties corresponding to the underlying features comprise petrophysical properties of a geological formation through which the wellbore has been drilled.

6. The system of claim 1, wherein the properties corresponding to the underlying features comprise fluid properties of a fluid in the wellbore.

7. The system of claim 1, wherein the data processing system is configured to identify at least one of the properties of the wellbore based on at least one of the underlying features and to present the properties visually in a well log.

8. The system of claim 1, wherein the matrix based on the multidimensional well-logging measurements comprises a column data matrix having values normalized to a normalization factor.

9. The system of claim 8, wherein the normalization factor comprises a sum of all components of a data vector that describes the multidimensional well-logging measurements, a mean of all components of the data vector, or a maximum of all components of the data vector, or any combination thereof.

10. A method comprising:
placing a downhole tool in a wellbore;
obtaining multidimensional well-logging measurements in the wellbore, wherein the multidimensional well-logging measurements comprise underlying features in varying proportions at different depths of the wellbore, wherein the underlying features or the varying proportions of the underlying features, or both, are not fully discernible to a human in the form of the multidimensional well-logging measurements as obtained by the downhole tool;
using one or more processors to predict or identify the underlying features or the varying proportions of the underlying features, or both, from the multidimensional well-logging measurements by decomposing a matrix based on the multidimensional well-logging measurements into a first component matrix and a second component matrix, wherein the first component matrix comprises basis vectors that describe the underlying features and the second component matrix comprises the varying proportions of the underlying features;
using the one or more processors to generate a visualization based on the underlying features or the varying proportions of the underlying features, or both, to enable well management based on the underlying features or the varying proportions of the underlying features, or both.

11. The method of claim 10, wherein the matrix based on the multidimensional well-logging measurements comprises a column data matrix, wherein the column data matrix has dimensions of N×M, where N represents the dimension of the measurement and M represents the number of realizations to be processed, and wherein the column data matrix is a product of the first component matrix and the second component matrix.

12. The method of claim 10, wherein predicting or identifying the underlying features or the varying proportions of the underlying features, or both, comprises:
normalizing the multidimensional well-logging measurements;
generating the matrix based on the multidimensional well-logging measurements by arranging the normalized multidimensional well-logging measurements into a column data matrix, wherein the column data matrix comprises a product of the first component matrix and the second component matrix; and
decomposing the column data matrix into the first component matrix and the second component matrix.

13. The method of claim 10, wherein predicting or identifying the underlying features or the varying proportions of the underlying features, or both, comprises decomposing the matrix based on the multidimensional well-logging measurements into the first component matrix and the second component matrix, including:
solving a first optimization problem to obtain basis vectors of the first component matrix that represent the underlying features of the multidimensional well-logging measurements; and
solving a second optimization problem to obtain values of the second component matrix that represent the proportions of the underlying features of the multidimensional well-logging measurements.

14. The method of claim 13, comprising normalizing the basis vectors after solving the first optimization problem and before solving the second optimization problem.

15. The method of claim 14, wherein the matrix based on the multidimensional well-logging measurements comprises a column data matrix that contains the multidimensional well-logging measurements normalized to a first normalization factor and wherein the basis vectors are normalized according to the same first normalization factor.
